(19) United States
(12) Patent Application Publication
(10) Pub. No.: US 2024/0410650 A1
(43) Pub. Date: Dec. 12, 2024

(54) SUBSTRATE PROCESSING APPARATUS AND SUBSTRATE PROCESSING METHOD

(71) Applicant: TES CO., LTD, Yongin-si (KR)

(72) Inventor: Hee-Jeon MA, Yongin-si (KR)

(73) Assignee: TES CO., LTD, Yongin-si (KR)

(21) Appl. No.: 18/738,070

(22) Filed: Jun. 10, 2024

(30) Foreign Application Priority Data
Jun. 12, 2023 (KR) 10-2023-0075187

(51) Int. Cl. F26B 5/00; H01L 21/02; H01L 21/67

(52) U.S. Cl. CPC F26B 5/005; H01L 21/02101; H01L 21/67017

(57) ABSTRACT

The present disclosure relates to a substrate processing apparatus and a substrate processing method, and more particularly, to a substrate processing apparatus and a substrate processing method for reaching a process pressure more quickly when a supercritical fluid is supplied into a chamber of the substrate processing apparatus using a supercritical fluid, thereby reducing a processing time and improving throughput.

### CROSS-REFERENCE TO RELATED APPLICATION

This application is based on and claims priority under 35 U.S.C. § 119 to Korean Patent Application No. 10-2023-0075187, filed on Jun. 12, 2023, in the Korean Intellectual Property Office, the disclosure of which is incorporated by reference herein in its entirety.

### TECHNICAL FIELD

The present disclosure relates to a substrate processing apparatus and a substrate processing method, and more particularly, to a substrate processing apparatus and a substrate processing method for reaching a process pressure more quickly when a supercritical fluid is supplied into a chamber of the substrate processing apparatus using a supercritical fluid, thereby reducing a processing time and improving throughput.

### BACKGROUND

In general, when large-scale/high-density semiconductor devices such as large-scale integration (LSI) are manufactured on a surface of a semiconductor wafer, it is necessary to form an ultrafine pattern on the surface of the wafer.

These ultrafine patterns may be formed by performing various processes of exposing, developing, and cleaning a wafer coated with resist, patterning the resist, and then etching the wafer to transfer the resist pattern to the wafer.

After this etching, the wafer is cleaned to remove dust or natural oxide films on the wafer surface. The cleaning process is performed by immersing the wafer with a surface on which a pattern is formed in a treatment liquid such as a chemical solution or a rinse liquid or by supplying the treatment liquid to the wafer surface.

However, as semiconductor devices become more highly integrated, pattern collapse, in which the pattern on the resist or the wafer surface collapses, occurs when the treatment liquid is dried after cleaning.

This pattern collapse corresponds to a phenomenon in which patterns 11, 12, and 13 collapse toward a side at which a large amount of the treatment liquid remains due to an imbalance in the capillary force of stretching the patterns 11, 12, and 13 to the left and right when the treatment liquid on the left and right sides of the patterns 11, 12, and 13 dries unevenly during the process of drying a treatment liquid 10 remaining on a surface of a substrate S after cleaning as shown in FIG. 11.

FIG. 11 shows a state in which a treatment liquid in left and right outer regions of an upper surface of the substrate S, in which a pattern is not formed, is completely dried, while the treatment liquid 10 remains in a gap between the patterns 11, 12, and 13. As a result, the patterns 11 and 13 on both the left and right sides collapse toward the inside due to the capillary force received from the treatment liquid 10 remaining between the patterns 11, 12, and 13.

The capillary force causing the pattern collapse described above is caused by an atmospheric atmosphere surrounding the substrate S after cleaning and a surface tension of the treatment liquid functioning at a liquid/gas interface with the treatment liquid remaining between patterns.

Therefore, recently, a treatment method of drying the treatment liquid by using a fluid in a supercritical state (hereinafter referred to as ‘supercritical fluid’) in which an interface between gas or liquid is not formed has attracted attention.

In a conventional drying method using only temperature control in a pressure and temperature phase diagram of FIG. 12, a gas-liquid equilibrium line is necessarily passed as shown by a hidden line, and in this case, capillary force is generated at a gas-liquid interface.

In contrast, when a fluid is dried through a supercritical state by using both temperature and pressure control of the fluid, a gas-liquid equilibrium line is not passed, and thus it is possible to dry a substrate in a state essentially free of capillary force.

With regard to drying using a supercritical fluid with reference to FIG. 12, when the pressure of a liquid is raised from A to B and the temperature is then raised from B to C, the liquid is converted into a supercritical state C without passing the gas-liquid equilibrium line. When the drying process is completed, the pressure of the supercritical fluid is lowered and converted to gas D without passing the gas-liquid equilibrium line.

When a supercritical fluid is used, a pump that supplies the supercritical fluid and a buffer tank that stores the supercritical fluid are provided, and the supercritical fluid is supplied from the buffer tank to the chamber by the pump and pressurized. In this case, the buffer tank and the chamber are simultaneously pressurized by the pump, and thus it takes a lot of time to reach a process pressure within the chamber, increasing the overall process time and reducing throughput.

### SUMMARY

To overcome the above problem, an object of the present disclosure is to provide a substrate processing apparatus and a substrate processing method for reaching a process pressure more quickly when a supercritical fluid is supplied into a chamber of the substrate processing apparatus using a supercritical fluid, thereby reducing the overall processing time and improving throughput.

According to an aspect of the present disclosure, a substrate processing apparatus includes a chamber that provides a processing space configured to perform a process on a substrate coated with a processing solution or organic solvent by using a fluid in a supercritical state, and a fluid supply unit configured to supply the fluid to the chamber, wherein the fluid supply unit includes a fluid storage configured to store the fluid, a main supply line connecting the fluid storage to the chamber, a pump provided on the main supply line to pressurize the fluid in the fluid storage and supply the fluid toward the chamber, a buffer tank provided at a rear end of the pump on the main supply line and configured to store the fluid, and a bypass line bypassing the buffer tank to connect the pump to the chamber.

The bypass line may branch off from the main supply line between the high-pressure pump and the buffer tank and may be merged with the main supply line between the buffer tank and the chamber.

The substrate processing apparatus may further include comprising a first orifice between the buffer tank and the chamber, and the bypass line may be merged with the main supply line of a front end of the first orifice.

The substrate processing apparatus may further include a first orifice between the buffer tank and the chamber, and the bypass line may be merged with the main supply line of a rear end of the first orifice. In this case, the substrate processing apparatus may further include a second orifice on the bypass line.

When the fluid is supplied toward the chamber and pressurized to a predetermined process pressure, provided may be a first pressurization step of supplying the fluid from the buffer tank toward the chamber, and a second pressurization step of supplying the fluid toward the chamber through the bypass line.

A converting point at which the first pressurization step is converted to the second pressurization step may be determined by at least one of a predetermined time of the first pressurization step or the second pressurization step, a pressure value inside the chamber, a pressure change rate inside the chamber, a pressure value inside the buffer tank, a pressure change rate inside the buffer tank, and a pressure difference between the chamber and the buffer tank.

When the pressure inside the chamber reaches a predetermined process pressure and a process for the substrate is performed, the fluid may be supplied toward the chamber through the bypass line and discharged from the chamber.

When the fluid is discharged from an inside of the chamber, the fluid may be discharged from the inside of the chamber and supplied to the buffer tank.

According to another aspect of the present disclosure, a substrate processing method of a substrate processing apparatus including a chamber for performing a process on a substrate by using a fluid in a supercritical state includes a pressurization step of supplying the fluid toward the chamber and pressurizing the fluid to a predetermined process pressure, an equal pressure operation of performing the process on the substrate, and a depressurization step of discharging the fluid from an inside of the chamber, wherein the pressurization step includes a first pressurization step of supplying the fluid from a buffer tank to the chamber, and a second pressurization step of supplying the fluid to the chamber through a bypass line bypassing the buffer tank.

A converting point at which the first pressurization step is converted to the second pressurization step may be determined by at least one of a predetermined time of the first pressurization step or the second pressurization step, a pressure value inside the chamber, a pressure change rate inside the chamber, and an internal pressure difference between the chamber and the buffer tank.

The equal pressure operation may include supplying the fluid toward the chamber through the bypass line and discharging the fluid from the chamber.

The depressurization step may include discharging the fluid from the inside of the chamber and supplying the fluid to the buffer tank.

### BRIEF DESCRIPTION OF THE DRAWINGS

Embodiments will be more clearly understood from the following detailed description taken in conjunction with the accompanying drawings in which:

FIG. 1 is a block diagram showing a configuration of a substrate processing apparatus using a supercritical fluid according to the related art;

FIG. 2 is a graph showing pressure changes inside a buffer tank and a chamber in FIG. 1;

FIG. 3 is a block diagram showing a configuration of a substrate processing apparatus according to the present disclosure;

FIG. 4 is a block diagram showing a configuration of a substrate processing apparatus according to another embodiment of the present disclosure;

FIG. 5 is a graph showing pressure changes inside a buffer tank and a chamber in FIG. 3;

FIGS. 6 to 10 are diagrams for explaining an operation of a substrate processing apparatus in each operation of a process for a substrate;

FIG. 11 is a schematic diagram showing a state in which a pattern collapses when the pattern on a substrate is dried according to the related art; and

FIG. 12 is a state diagram showing pressure and temperature changes in a fluid in a process using a supercritical fluid.

### DETAILED DESCRIPTION OF THE EMBODIMENTS

Hereinafter, a structure of a substrate processing apparatus according to an embodiment of the present disclosure will be examined in detail with reference to the drawings.

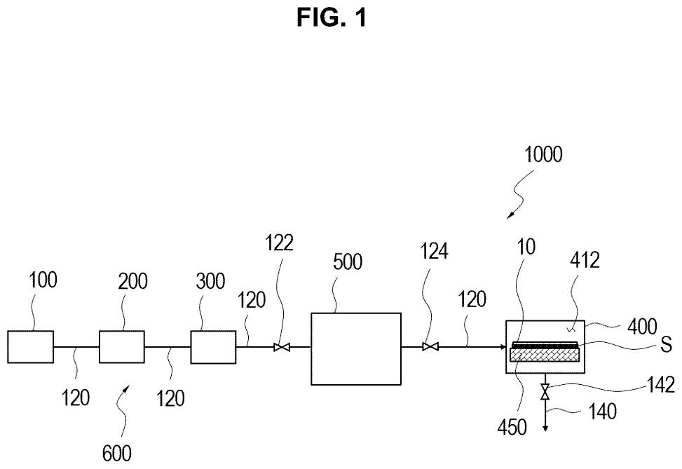

FIG. 1 is a block diagram showing a configuration of a substrate processing apparatus 1000 according to the related art.

The substrate processing apparatus 1000 using a supercritical fluid performs a process on a substrate S by using a fluid in a supercritical state. Here, a fluid in a supercritical state corresponds to a fluid with a phase in which a material reaches a critical state, that is, a state exceeding a critical temperature and a critical pressure. The fluid in a supercritical state has a molecular density close to that of a liquid, but a viscosity close to that of a gas. Therefore, since the fluid in a supercritical state has excellent diffusion, penetration, and dissolving power, which is advantageous for chemical reactions and does not apply surface tension to a microstructure due to almost no surface tension, the fluid in a supercritical state not only has excellent drying efficiency during a drying process of semiconductor devices, but also is capable of avoiding pattern collapse, and thus may be very useful.

In the present disclosure, carbon oxide (CO₂) may be used as a supercritical fluid. Carbon dioxide has a critical temperature of approximately 31.1° C. and a relatively low critical pressure of 7.38 Mpa, and thus it is advantageous that carbon dioxide is easily converted to a supercritical state, the state of carbon dioxide is controlled by adjusting the temperature and the pressure thereof, and carbon dioxide is inexpensive.

Carbon dioxide is non-toxic, harmless to the human body, and has properties of being non-flammable and inert. Since carbon dioxide in a supercritical state has a diffusion coefficient that is approximately 10 to 100 times higher than that of water or other organic solvents, carbon dioxide has excellent permeability, allows rapid substitution of organic solvents, and has almost no surface tension, and thus has properties that are advantageous for use in a drying process. It is possible to convert carbon dioxide used in the drying process into a gaseous state, separate the organic solvent, and reuse the same, thus reducing a burden in terms of environmental pollution.

Referring to FIG. 1, the substrate processing apparatus 1000 may include a chamber 400 that provides a processing space 412 in which a process for the substrate S coated with a treatment liquid or organic solvent 10 (hereinafter referred to as ‘organic solvent’) by using a liquid in a supercritical state, and a fluid supply unit 600 that supplies a fluid to the chamber 400.

The fluid supply unit 600 may supply a fluid to the chamber 400 through a main supply line 120 by adjusting at least one of the temperature and pressure of the fluid.

For example, the fluid supply unit 600 may include a fluid storage 100 that stores the fluid, and the main supply line 120 connecting the fluid storage 100 and the chamber 400 to each other.

In this case, a temperature controller 200 and a pump 300 for controlling pressure may be located on the main supply line 120. In this case, the temperature controller 200 may include a heater heating the fluid or a heat exchanger.

The main supply line 120 may further include a detector (not shown) that detects at least one of the pressure and temperature of the fluid. The pressure and temperature of the fluid flowing in the main supply line 120 may be adjusted according to the pressure and temperature detected by the detector. To this end, the substrate processing apparatus 1000 according to an embodiment of the present disclosure may include a controller (not shown) that controls the pump 300 and the temperature controller 200. The controller may control the pump 300 and the temperature controller 200 based on the pressure and temperature detected by the detector.

When a process is performed on the substrate S, the temperature and pressure of the processing space 412 of the chamber 400 need to be maintained above the critical temperature and critical pressure to convert the fluid supplied into the chamber 400 into a supercritical state.

To this end, while the fluid moves along the main supply line 120, the fluid may be pressurized to a critical pressure or higher by the pump 300, and also the fluid may be heated to a critical temperature or higher by the temperature controller 200.

The main supply line 120 may further include the buffer tank 500 to store the fluid. The buffer tank 500 serves to rapidly supply the fluid when storing the fluid and supplying the fluid to the chamber 400.

For example, an internal space of the buffer tank 500 may have a larger volume than an internal space of the chamber 400. Accordingly, the fluid inside the buffer tank 500, which has a larger capacity than the chamber 400, may be supplied to the chamber 400, thereby supplying the fluid more quickly.

In this case, the buffer tank 500 may be located at a rear end of the pump 300 on the main supply line 120. A first valve 122 may be provided at a front end of the buffer tank 500 to control a flow of the fluid, and a second valve 124 may be provided at a rear end of the buffer tank 500 to control supply of the fluid.

The chamber 400 may further include a discharge line 140 for discharging the fluid in the processing space 412 to the outside. During the process for the substrate S or when the process is completed, fluid may be discharged from the inside of the chamber 400 to the outside through the discharge line 140. The discharge line 140 may include a discharge valve 142, and may include, for example, a proportional valve.

The chamber 400 may provide the processing space 412 for performing a process such as a drying process on the substrate S by using a fluid in a supercritical state. The chamber 400 may have an opening (not shown) formed at one side and may be formed of a material to process a high-pressure process for the substrate S inside the chamber 400.

The processing space 412 of the chamber 400 is maintained in a sealed state, and thus the pressure of the fluid supplied to the processing space 412 may be maintained above the critical pressure.

The chamber 400 may further include a heater (not shown) to maintain the temperature of the processing space 412 above a certain temperature. The heater may maintain the temperature of the processing space 412 or the temperature of the fluid stored in the processing space 412 above a critical temperature during the process for the substrate S.

The chamber 400 may include a tray 450 that supports the substrate S.

The tray 450 may be retracted into the processing space 412 of the chamber 400 through the above-described opening of the chamber 400, or is extended out of the chamber 400 through the opening in the processing space 412.

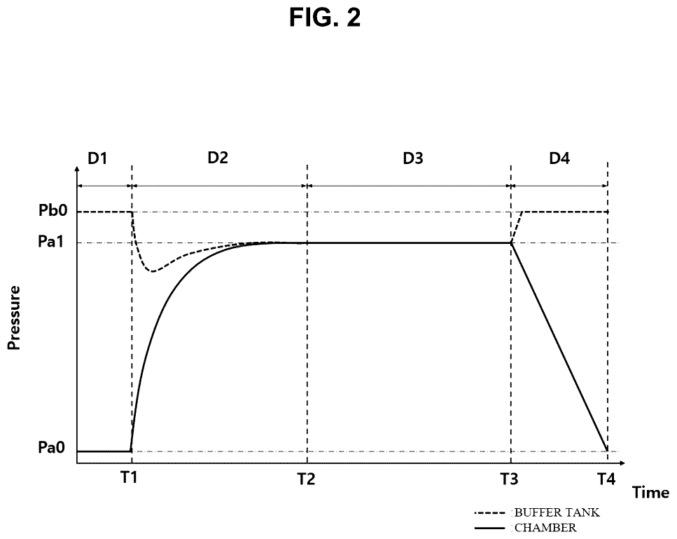

FIG. 2 is a graph showing pressure changes inside the buffer tank 500 and the chamber 400 according to a process for the substrate S in the substrate processing apparatus 1000.

Hereinafter, a process for the substrate S of the substrate processing apparatus 1000 will be described with reference to the drawings.

Referring to FIGS. 1 and 2, in the case of a preparation operation D1: 0 to T1 in which the process for the substrate S begins and the tray 450 is retracted and docked inside the chamber 400, the pressure inside the chamber 400 may correspond to atmospheric pressure Pa0. The buffer tank 500 may already store the fluid therein and maintain a predetermined initial pressure Pb0.

In this case, the above-described first valve 122 remains open, and the second valve 124 remains closed.

Then, a pressurization step D2: T1 to T2 in which the pressure inside the chamber 400 increases follows.

In the pressurization step, the second valve 124 is opened to supply a high-pressure fluid of the buffer tank 500 into the chamber 400 by driving the pump 300, and the fluid may not be discharged from the chamber 400 to the outside. Accordingly, the pressure inside the chamber 400 increases and reaches a predetermined process pressure Pa1.

In more detail, when the high-pressure fluid of the buffer tank 500 is supplied to the chamber 400 by driving the pump 300, the internal pressure of the buffer tank 500 at the beginning of the pressurization step decreases rapidly, while the pressure inside the chamber 400 rapidly increases.

Then, with regard to a later part of the pressurization step, the pressure of the buffer tank 500 rises again as fluid is continuously supplied from the fluid storage 100 by driving the pump 300. Although the pressure inside the chamber 400 continues to rise, as the pressure approaches a process pressure, the pressure rises at a significantly slower rise rate compared to an initial rise rate.

When the internal pressure of the buffer tank 500 and the chamber 400 reaches a predetermined process pressure Pa1, the pressurization step is terminated.

The pressurization step is followed by a pressure maintaining operation (or equal pressure operation) D3: T2 to T3. In the pressure maintaining operation, the above-described discharge valve 142 is opened. Therefore, while continuously supplying fluid into the chamber 400, the fluid is discharged to the outside of the chamber 400 through the discharge line 140 equal to the amount of the supplied fluid, thereby remaining constant the pressure inside the chamber 400.

The above-described pressure maintaining operation is followed by a depressurization step D4: T3 to T4. In the depressurization step, the second valve 124 may be closed to not supply fluid into the chamber 400, but the fluid is discharged to the outside of the chamber 400 through the discharge line 140, thereby reducing the pressure inside the chamber 400.

In this case, the second valve 124 is closed, and thus the pressure of the buffer tank 500 increases, and when the initial pressure Pb0 is reached, the first valve 122 may be closed.

As described above, in the pressurization step D2: T1 to T2, the pressure inside the chamber 400 rises rapidly in the beginning, but as the pressure approaches the process pressure Pa1 in the later part of the current operation, the pressure rise rate inside the chamber 400 decreases. This is because the buffer tank 500 and the chamber 400 are connected and both the buffer tank 500 and the chamber 400 are pressurized by the pump 300. In particular, as described above, the buffer tank 500 has a larger capacity than the chamber 400, and thus a large load is applied to the pump 300 to delay a time to reach the process pressure inside the chamber 400, thereby increasing the overall process time and reducing throughput.

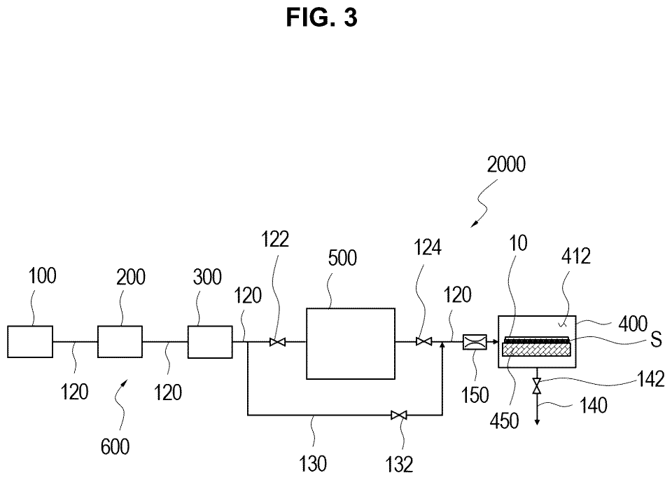

FIG. 3 is a block diagram showing a configuration of a substrate processing apparatus 2000 according to the present disclosure to resolve the above-described problem. In FIG. 3, the same reference numerals are used for the same components as those in FIG. 1 described above.

Referring to FIG. 3, the substrate processing apparatus 2000 may include a bypass line 130 that connects the pump 300 and the chamber 400 by bypassing the buffer tank 500.

For example, the bypass line 130 may branch off from the main supply line 120 between the pump 300 and the buffer tank 500 and may be merged with the main supply line 120 between the buffer tank 500 and the chamber 400. In more detail, the bypass line 130 may branch from the main supply line 120 at a front end of the above-described first valve 122 and may be merged with the main supply line 120 at a rear end of the above-described second valve 124.

In this case, the bypass line 130 may include a third valve 132 that controls a flow of the fluid.

A first orifice 150 may be located at the rear end of the above-described second valve 124 on the main supply line 120. The first orifice 150 serves to control a flow rate or pressure of the fluid supplied to the chamber 400 to prevent the substrate S from being damaged due to a rapid supply of fluid to the chamber 400.

For example, the bypass line 130 may be merged with the main supply line 120 at a rear end of the first orifice 150. In more detail, the bypass line 130 may be merged with the main supply line 120 between the rear end of the above-described second valve 124 and the front end of the first orifice 150.

In this case, even when the fluid is supplied through the buffer tank 500 or the bypass line 130, a flow rate or pressure of the fluid may be advantageously adjusted by the first orifice 150.

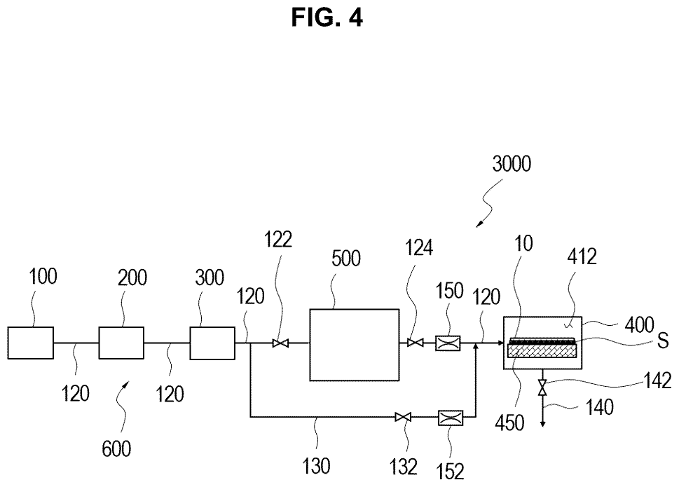

FIG. 4 is a block diagram showing a configuration of a substrate processing apparatus 3000 according to another embodiment of the present disclosure. In FIG. 4, the same reference numerals are used for the same components as those in the embodiment described above.

Referring to FIG. 4, in the present embodiment, the bypass line 130 may be merged with the main supply line 120 at the rear end of the first orifice 150. A second orifice 152 may be located in the bypass line 130.

In this case, the flow rate and pressure of the fluid supplied through the buffer tank 500 may be controlled by the first orifice 150, and the flow rate and pressure of the fluid supplied through the bypass line 130 may be controlled by the second orifice 152.

The inner diameters or sizes of the first orifice 150 and the second orifice 152 may be the same, but may be determined differently. When the inner diameters of the first orifice 150 and the second orifice 152 are different from each other, the flow rate and pressure of the fluid supplied through the buffer tank 500 and the fluid supplied through the bypass line 130 may be advantageously differently adjusted.

In the substrate processing apparatuses 2000 and 3000 of FIGS. 3 and 4, high-pressure fluid may bypass the buffer tank 500 to be supplied to the chamber 400 through the bypass line 130 during the pressurization step of the substrate process, thereby reducing a time of the pressurization step and shortening the overall process time by approximately 50% or more compared to the related art. Hereinafter, this will be described in detail.

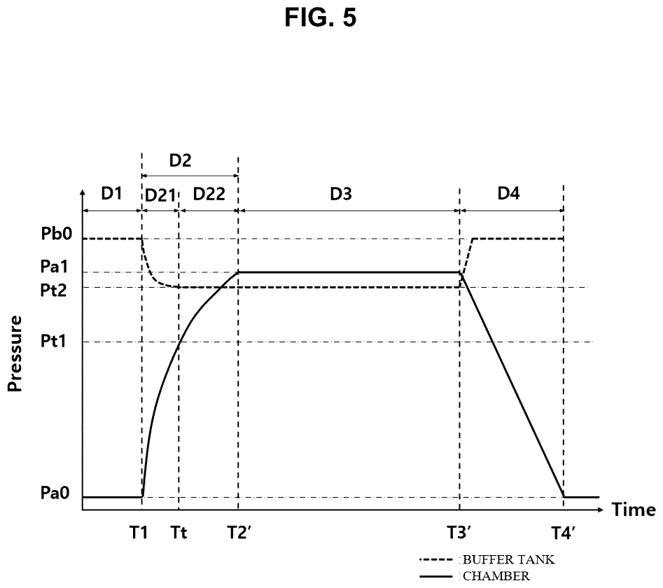

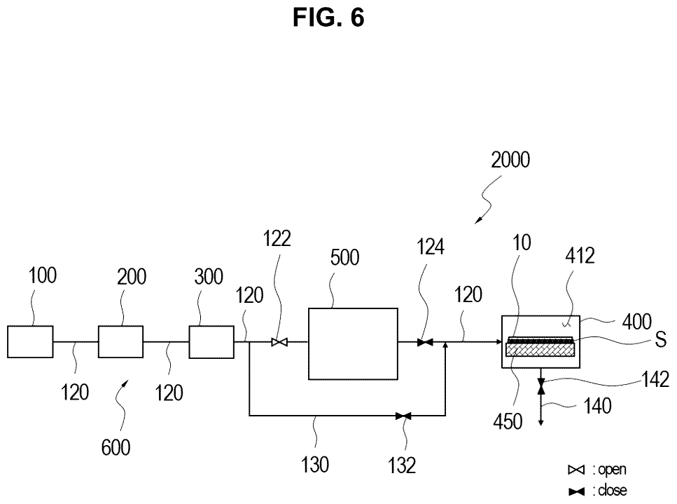

FIG. 5 is a graph showing pressure changes inside the buffer tank 500 and the chamber 400 according to a process for the substrate S in the above-described substrate processing apparatus 2000, and FIGS. 6 to 10 are diagrams for explaining an operation of the substrate processing apparatus 2000 in each operation of the process for the substrate S. In FIGS. 6 to 10, the above-described orifice is omitted for convenience of explanation.

Referring to FIGS. 5 and 6, in the case of a preparation operation D1: 0 to T1 in which a process for the substrate S begins and the tray 450 is retracted into the chamber 400, the pressure inside the chamber 400 may correspond to atmospheric pressure Pa0, and the buffer tank 500 may already store the fluid therein and maintain a predetermined initial pressure Pb0.

In this case, the above-described first valve 122 remains open, and the second valve 124 and the third valve 132 remain closed.

Then, referring to FIGS. 5 and 7 to 8, a pressurization step D2: T1 to T2′ in which the pressure inside the chamber 400 increases is followed.

In the substrate processing apparatus 2000 according to the present disclosure, the pressurizing operation may include a first pressurization step D21: T1 to Tt of supplying the fluid from the buffer tank 500 to the chamber 400 and a second pressurization step D22: Tt to T2′ of supplying the fluid to the chamber 400 through the bypass line 130 that bypasses the buffer tank 500.

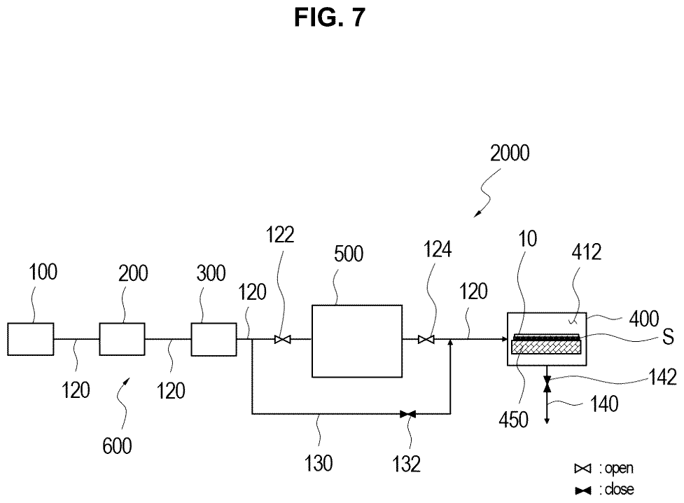

First, in the first pressurization step, as shown in FIG. 7, the second valve 124 is opened to allow the high-pressure fluid of the buffer tank 500 to be supplied into the chamber 400 by driving the pump 300 described above. Accordingly, the pressure inside the chamber 400 increases.

Subsequently, the first pressurization step may be converted to a second pressurization step. Here, a converting point Tt at which the first pressurization step is converted to the second pressurization step is determined by at least one of a predetermined time of the first pressurization step or the second pressurization step, a pressure value inside the chamber 400, a pressure change rate (or pressure rise rate) inside the chamber 400, a pressure value inside the buffer tank 500, a pressure change rate inside the buffer tank 500, and an internal pressure difference between the chamber 400 and the buffer tank 500.

For example, a time of the first pressurization step may be predetermined, and when the predetermined time elapses, the first pressurization step may be converted to the second pressurization step.

Alternatively, the pressure value inside the chamber 400 may be compared with a predetermined reference pressure value Pt1, and when the pressure value inside the chamber 400 reaches the reference pressure value, the first pressurization step may be converted to the second pressurization step. Here, the reference pressure value may be determined as a critical pressure value of the fluid, for example, but this is only an example and may be determined in various ways depending on a process for the substrate S.

The pressure change rate (or pressure rise rate) inside the chamber 400 may be detected and the first pressurization step may be converted to the second pressurization step according to the pressure rise rate inside the chamber 400. For example, when the fluid is supplied to the chamber 400 through the bypass line 130 in the second pressurization step, the pressure rise rate inside the chamber 400 (hereinafter referred to as ‘second pressure rise rate’) may be predetermined. Therefore, in the above-described first pressurization step, the pressure rise rate inside the chamber 400 (hereinafter referred to as ‘first pressure rise rate’) is compared with the second pressure rise rate, and when the first pressure rise rate is equal to or less than the second pressure rise, the first pressurization step may be converted to the second pressurization step.

Alternatively, the pressure value inside the buffer tank 500 may be compared with a predetermined reference pressure value, and when the pressure value inside the buffer tank 500 reaches the reference pressure value, the first pressurization step may be converted to the second pressurization step. Here, the reference pressure value may be determined in various ways depending on the process for the substrate S.

The pressure change rate (or pressure rise rate) inside the buffer tank 500 may be detected and the first pressurization step may be converted to the second pressurization step according to the pressure rise rate inside the buffer tank 500.

An internal pressure difference between the chamber 400 and the buffer tank 500 is compared with a predetermined reference value, and when the internal pressure difference between the chamber 400 and the buffer tank 500 is equal to or less than the reference value, the first pressurization step may be converted to the second pressurization step.

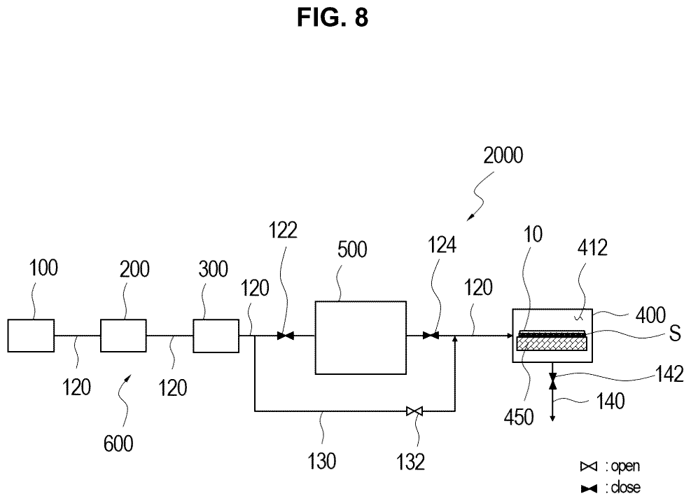

In the above-described second pressurization step, as shown in FIG. 8, both the first valve 122 and the second valve 124 are closed and the third valve 132 is opened.

Accordingly, the high-pressure fluid supplied by driving the pump 300 may bypass the buffer tank 500 without passing therethrough and be supplied to the chamber 400 through the bypass line 130. When the fluid is supplied by driving the pump 300, the fluid is supplied directly to the chamber 400 without passing through the buffer tank 500 with a high capacity, and thus the pressure inside the chamber 400 may be raised more quickly.

In this case, as shown in FIG. 5, the pressure rise rate inside the chamber 400 after the converting point Tt at which the first pressurization step is converted to the second pressurization step may be greater than a rise rate in the later part of the pressurization step of FIG. 2 described above. Therefore, the pressure inside the chamber 400 may reach the process pressure Pa1 in an earlier time than in the related art in FIG. 2.

The pressure inside the buffer tank 500 remains at the pressure Pt2 at the converting time point Tt. This is because, as shown in FIG. 8, both the first valve 122 and the second valve 124 at the front and rear ends of the buffer tank 500 are closed.

When the internal pressure of the chamber 400 reaches a predetermined process pressure Pa1, the pressurization step is terminated.

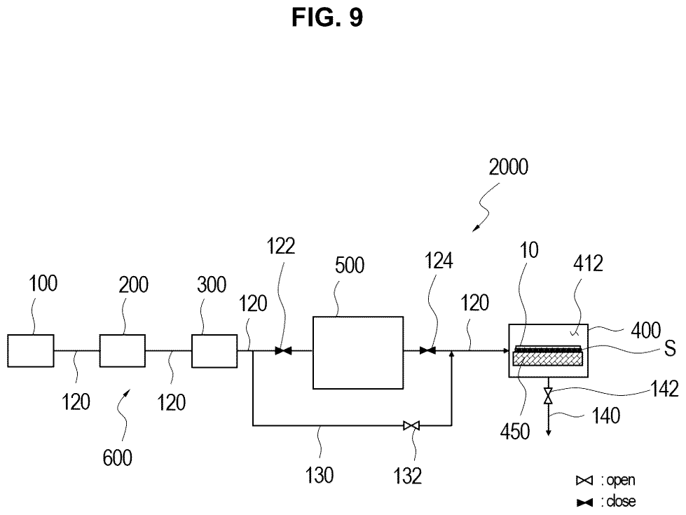

The pressurization step is followed by a process operation D3: T2′ to T3′. In the process operation, the above-described discharge valve 142 is opened as shown in FIG. 9. Therefore, while continuously supplying fluid into the chamber 400 through the bypass line 130, fluid is discharged out of the chamber 400 through the discharge line 140.

In this case, fluid is discharged through the discharge line 140 equal to the amount of fluid supplied into the chamber 400, and the pressure inside the chamber 400 is maintained constant in the process operation.

Alternatively, in the process operation, the pressure inside the chamber 400 may be varied in a pulsed manner to vary the pressure inside said chamber 400 so that the fluid is evenly spread into the inside of the chamber 400.

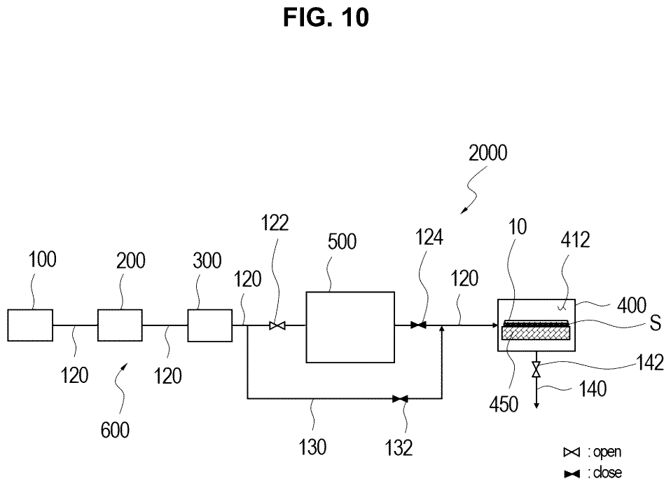

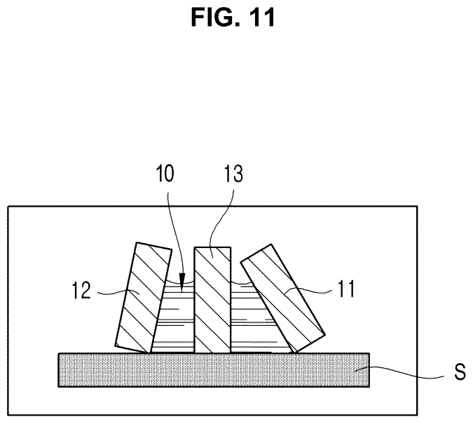

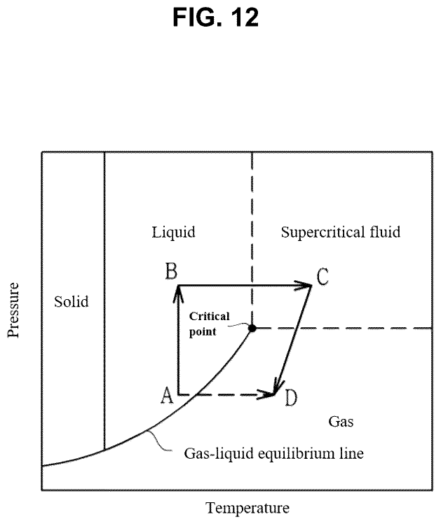

The above-described process operation is followed by a depressurization step D4: T3′ to T4′. In the depressurization step, as shown in FIG. 10, the third valve 132 may be closed to not supply fluid into the chamber 400, but the fluid is discharged to the outside of the chamber 400 through the discharge line 140, thereby reducing the pressure inside the chamber 400.

In this case, the second valve 124 is closed and the first valve 122 is open, and thus fluid is supplied to the buffer tank 500 such that the pressure inside the buffer tank 500 increases, and when the initial pressure Pb0 is reached, the first valve 122 may be closed.

According to the present disclosure having the above-described configuration, when supercritical fluid is supplied to the chamber and pressurized to the process pressure, a time to reach the process pressure is shortened by bypassing the buffer tank and supplying the supercritical fluid to the chamber, thereby reducing the overall process time and improving throughput.

Although the present disclosure has been described above with reference to exemplary embodiments, those skilled in the art may modify and change the present disclosure in various ways without departing from the spirit and scope of the present disclosure as set forth in the claims described below. Therefore, when the modified implementation basically includes the elements of the claims of the present disclosure, it should be considered to be included in the technical scope of the present disclosure.

What is claimed is:

1. A substrate processing apparatus comprising:
a chamber that provides a processing space configured to perform a process on a substrate coated with a processing solution or organic solvent by using a fluid in a supercritical state; and
a fluid supply unit configured to supply the fluid to the chamber,
wherein the fluid supply unit includes:
a fluid storage configured to store the fluid;
a main supply line connecting the fluid storage to the chamber;
a pump provided on the main supply line to pressurize the fluid in the fluid storage and supply the fluid toward the chamber;
a buffer tank provided at a rear end of the pump on the main supply line and configured to accommodate the fluid; and
a bypass line bypassing the buffer tank to connect the pump to the chamber.

2. The substrate processing apparatus of claim 1, wherein the bypass line branches off from the main supply line between the pump and the buffer tank and is merged with the main supply line between the buffer tank and the chamber.

3. The substrate processing apparatus of claim 2, further comprising a first orifice between the buffer tank and the chamber on the main supply line,
wherein the bypass line is merged with the main supply line of a front end of the first orifice.

4. The substrate processing apparatus of claim 2, further comprising a first orifice between the buffer tank and the chamber on the main supply line,
wherein the bypass line is merged with the main supply line of a rear end of the first orifice.

5. The substrate processing apparatus of claim 4, further comprising a second orifice on the bypass line.

6. The substrate processing apparatus of claim 1, wherein, when the fluid is supplied toward the chamber and pressurized to a predetermined process pressure, a first pressurization step of supplying the fluid from the buffer tank toward the chamber, and a second pressurization step of supplying the fluid toward the chamber through the bypass line are provided.

7. The substrate processing apparatus of claim 6, wherein a converting point at which the first pressurization step is converted to the second pressurization step is determined by at least one of a predetermined time of the first pressurization step or the second pressurization step, a pressure value inside the chamber, a pressure change rate inside the chamber, a pressure value inside the buffer tank, a pressure change rate inside the buffer tank, and a pressure difference between the chamber and the buffer tank.

8. The substrate processing apparatus of claim 1, wherein, when the pressure inside the chamber reaches a predetermined pressure and a process for the substrate is performed, the fluid is supplied toward the chamber through the bypass line and the fluid is discharged from the chamber.

9. The substrate processing apparatus of claim 1, wherein, when the fluid is discharged from an inside of the chamber, the fluid is discharged from the inside of the chamber and fluid is supplied to the buffer tank from the fluid storage.

10. A substrate processing method of a substrate processing apparatus including a chamber for performing a process on a substrate by using a fluid in a supercritical state, the method comprising:
a pressurization step of supplying the fluid toward the chamber and pressurizing the fluid to a predetermined pressure;
a process step of performing the process on the substrate; and
a depressurization step of discharging the fluid from an inside of the chamber,
wherein the pressurization step includes:
a first pressurization step of supplying the fluid from a buffer tank to the chamber; and
a second pressurization step of supplying the fluid to the chamber through a bypass line bypassing the buffer tank.

11. The method of claim 10, wherein a converting point at which the first pressurization step is converted to the second pressurization step is determined by at least one of a predetermined time of the first pressurization step or the second pressurization step, a pressure value inside the chamber, a pressure change rate inside the chamber, and an internal pressure difference between the chamber and the buffer tank.

12. The method of claim 10, wherein the process step includes supplying the fluid toward the chamber through the bypass line and discharging the fluid from the chamber.

13. The method of claim 10, wherein the depressurization step includes discharging the fluid from the inside of the chamber and supplying fluid to the buffer tank from the fluid storage.
